(19) United States
(12) Patent Application Publication
(10) Pub. No.: US 2003/0173584 A1
(43) Pub. Date: Sep. 18, 2003

(54) Semiconductor integrated circuit device and method of fabricating the same

(75) Inventor: Junichiro Nikaido, Yamanashi (JP)

Correspondence Address: ARMSTRONG,WESTERMAN & HATTORI, LLP, 1725 K STREET, NW, SUITE 1000, WASHINGTON, DC, 20006, US

(73) Assignee: FUJITSU QUANTUM DEVICES LIMITED, Yamanashi (JP)

(21) Appl. No.: 10/348,008

(22) Filed: Jan. 22, 2003

(30) Foreign Application Priority Data
Mar. 14, 2002 (JP) 2002-070967

(51) Int. Cl. H01L 31/0328

(52) U.S. Cl. 257/194

(57) ABSTRACT

A semiconductor integrated circuit device includes a semiconductor layer on a substrate, a first gate electrode formed on the semiconductor layer, and a second gate electrode that is formed on the semiconductor layer and is adjacent to a sidewall of the first gate electrode along a channel length. The first and second gate electrodes have different work functions.

### BACKGROUND OF THE INVENTION

1. Field of the Invention

The present invention relates to a semiconductor integrated circuit device having gate electrodes of different work functions and a method of fabricating the same.

2. Description of the Related Art

Japanese Unexamined Patent Publication No. 6-283725 discloses a semiconductor integrated circuit device in which two gate electrodes are provided on a semiconductor substrate and are made of materials having different work functions. The device disclosed in the above application is described with reference to FIG. 1. On a semi-insulating GaAs substrate 1, provided are an i-GaAs bffer layer 2, an i-AlGaAs spacer layer 3, an n-type AlGaAs carrier supply layer 4, and an n-type GaAs layer 5, these layers being epitaxially grown in this order. The n-type AlGaAs carrier supply layer 4 is exposed in a recess formed in the n-type GaAs layer 5. A first-stage gate electrode 9a and a second-stage gate electrode 9b are formed on the top of the n-type AlGaAs carrier supply layer 4 exposed in the recess. A source electrode 7 and a drain electrode 8, which are made by ohmic contacts, are formed on the n-type GaAs layer 5. The layers 1 through 4 define a HEMT (High Electron Mobility Transistor) layer 6. A palladium layer 9a that underlies the first-stage gate electrode 9a is provided in order to make the work function of the first-stage gate electrode 9a higher than that of the second-stage gate electrode 9b made of Al. The gate electrodes 9a and 9b are away from each other and are made of materials having different work functions, so that the depletion layer at the side of the drain electrode 8 can be made smaller than that at the side of the source electrode 7.

However, the device shown in FIG. 1 has a disadvantage in that separate gate wiring lines must be provided because the gate electrodes 9a and 9b are separately provided.

There is another disadvantage described below. A surface depletion layer 11 is interposed between the gate electrodes 9a and 9b spaced apart from each other. The surface depletion layer 11 cannot be bias-modulated. When a gate voltage is applied to the gate electrodes 9a and 9b, large steps 12 and 13 of the depletion layer are formed in the vicinity of edges of the gate electrodes 9a and 9b. The electric field from the drain electrode 8 concentrates at the steps 12 and 13. This concentration of the electric field degrades the breakdown voltage between the gate and drain.

There is yet another disadvantage. When the gate electrodes 9a and 9b and the recess length (the size of the recess formed in the n-type GaAs layer 5) are miniaturized, there is difficulty in accurately positioning and arranging the gate electrodes 9a and 9b on the recess surface.

### SUMMARY OF THE INVENTION

It is a general object of the present invention to provide a semiconductor integrated circuit device and a method of fabricating the same, in which the above disadvantages are eliminated.

A more specific object of the present invention is to provide a high-breakdown-voltage semiconductor integrated circuit device that is equipped with gate electrodes to which gate wiring lines can easily be arranged and that can be miniaturized easily.

The above objects of the present invention are achieved by a semiconductor integrated circuit device comprising: a semiconductor layer on a substrate; a first gate electrode formed on the semiconductor layer; and a second gate electrode that is formed on the semiconductor layer and is adjacent to a sidewall of the first gate electrode along a channel length, the first and second gate electrodes having different work functions.

The above objects of the present invention are achieved by a method of fabricating a semiconductor integrated circuit device comprising the steps of: (a) forming a mask on a semiconductor layer provided on a substrate so that the mask has an overhang portion that extends along a channel length; (b) depositing a first gate electrode material via the mask; (c) depositing a second gate electrode material on the semiconductor layer so as to be adjacent to a sidewall of the first gate electrode material, the second gate electrode material having a work function different from that of the first gate electrode material.

### BRIEF DESCRIPTION OF THE DRAWINGS

Other objects, features and advantages of the present invention will become more apparent from the following detailed description when read in conjunction with the accompanying drawings, in which:

FIG. 1 is a cross-sectional view of a conventional semiconductor integrated circuit device having two gate electrodes;

FIG. 2 is a cross-sectional view of a semiconductor integrated circuit device according to a first embodiment of the present invention;

FIGS. 3A through 3D illustrate steps of a method of fabricating the device shown in FIG. 2;

FIGS. 4A through 4D illustrate steps of another method of fabricating the device shown in FIG. 2;

FIGS. 5A through 5D illustrate steps of yet another method of fabricating the device shown in FIG. 2;

FIG. 6 is a cross-sectional view of a semiconductor integrated circuit device according to a second embodiment of the present invention;

FIG. 7 is an enlarged cross-sectional view of the device shown in FIG. 6; and

FIGS. 8A through 8C illustrate steps of a method of fabricating the device shown in FIG. 6.

### DESCRIPTION OF THE PREFERRED EMBODIMENTS

A description will now be given of embodiments of the present invention with reference to the accompanying drawings.

(First Embodiment)

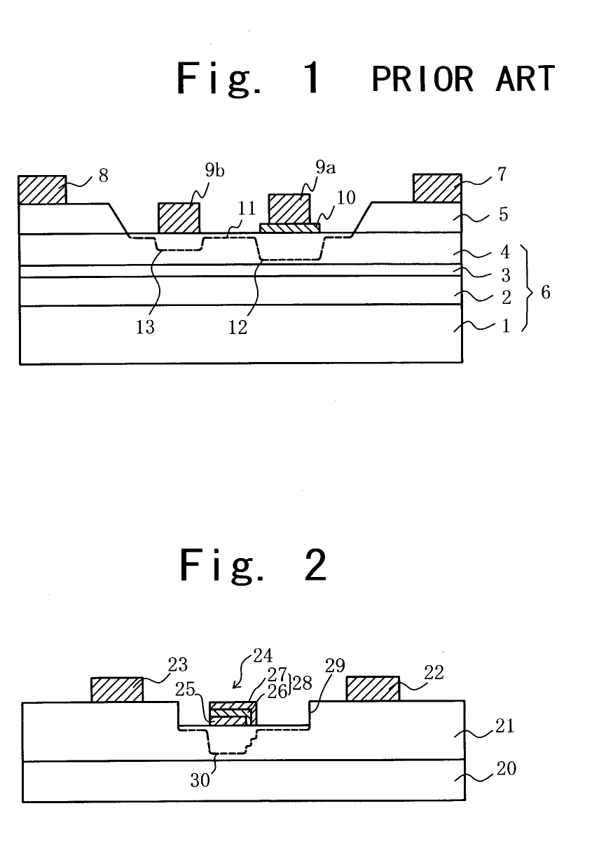

FIG. 2 is a cross-sectional view of a semiconductor integrated circuit device according to a first embodiment of the present invention. The device shown in FIG. 2 is a MESFET (Metal Semiconductor Field Effect Transistor) composed of compound semiconductors.

An n-type GaAs epitaxial layer (channel layer) 21 is formed on a semi-insulating GaAs substrate 20. The GaAs epitaxial layer 21 has a recess region 29, in which a gate electrode 24 is formed. A drain electrode 22 and a source electrode 23 are arranged at both sides of the gate electrode 24 and are provided on the GaAs epitaxial layer 21. Each of the drain electrode 22 and the source electrode 23 has a multilayer structure such as AuGe/Ni/Au.

The gate electrode 24 includes a first gate electrode 25 and a second gate electrode 28, these electrodes being integrally formed. The second gate electrode 28 is adjacent to one of opposing sides of the first gate electrode 25 in the direction in which a channel runs. The term “adjacent to” includes a first case where the second gate electrode 28 contacts the first gate electrode 25, and a second case where the second gate electrode 28 is spaced apart from the first gate electrode 25 within a range in which there is a small influence of the surface depletion layer, as will be described later. In the structure shown in FIG. 2, the second gate electrode 28 is adjacent to the first gate electrode 25 so as to contact it. Thus, there is no surface depletion layer between the first gate electrode 25 and the second gate electrode 28. The first gate electrode 25 controls a current that flows in the GaAs epitaxial layer 21. The second gate electrode 28 relaxes the electric field between the gate and drain. The second gate electrode 28 has a vertical portion that is in contact with the GaAs epitaxial layer 21 and is located at the side of the drain electrode 22.

The second gate electrode 28 has a two-layer structure composed of electrode layers 26 and 27. Therefore, it can be said that the gate electrode 24 is made up of three layers 25, 26 and 27.

The first gate electrode 25 is wider than the second gate electrode 28 along the channel length. The first gate electrode 25 mainly controls flow of electrons (current) in the GaAs epitaxial layer 21. The first gate electrode 25 and the second gate electrode 28 have mutually different work functions. More particularly, the first gate electrode 25 has a work function greater than that of the second gate electrode 28. The electrode layers 26 and 27 have different work functions. More particularly, the work function of the electrode layer 26 is greater than that of the electrode layer 27. In other words, the second gate electrode 28 has the electrode layers26 and 27, which have respective work functions that become smaller in order from the first gate electrode 25 towards the drain electrode 22. With the above arrangement, the depletion layer (indicated by a broken line 30 in FIG. 2) developed by applying a gate voltage to the gate electrode 24 becomes shallower in the order of the first gate electrode 25, the electrode layer 26 and the electrode layer 27. The depletion layer 30 has a gentle slope as a whole although the depletion layer 30 has steps that depend on the above-mentioned work functions. Thus, the electric lines of force from the drain side spread over the gentle slope of the depletion layer 30, so that the gate-drain breakdown voltage can be improved.

The first gate electrode 25 may be made of a material selected from a group of palladium, aluminum, titanium, tungsten, tungsten silicide, titanium tungsten, nickel, platinum, gold, silver, copper, indium, magnesium, tantalum, molybdenum, antimony, chromium, tin, tungsten nitride, and titanium tungsten nitride. The second gate electrode 28 may be a material selected from the above group except one selected for the first gate electrode 25. As has been described previously, the materials of the gate electrodes 25 through 27 are selected so that the work function decreases in the order of the first gate electrode 25, the electrode layer 26 and the electrode layer 27.

The second gate electrode 28 is not limited to the two-layer structure. The second gate electrode 28 may be a single-layer structure or a multilayer structure composed of three layers or more. Principally, as the number of electrode layers for the second gate electrode 28 increases, the steps of the depletion layer become smoother, so that the relaxation of the electric field can be facilitated. In contrast, the number of production steps increases.

The electrode layers 26 and 27 have cross sections each having an inverted L shape. This is due to the use of a single window with which the gate electrode 24 having the three-layer structure is formed, as will be described later. In light of relaxation of the electric field, it is not necessary to laminate the electrode layers 26 and 27 on the gate electrode 25 in this order. It is enough for the electrode layers 26 and 27 to be arranged adjacent to each other and to contact the GaAs epitaxial layer 21.

The following effects are brought by the first embodiment of the present invention. First, the single gate electrode 24 can be constructed so that the first gate electrode 25 and the second gate electrode 28 are adjacent to each other so as to contact each other. Therefore, a single gate wiring line can be used to make a connection with the gate electrode 24. Second, the second gate electrode 28 that has a smaller work function than the first gate electrode 25 is arranged adjacent thereto, so that the depletion layer at the drain side varies gently and the concentration of the electric field can be relaxed. This improves the gate-drain breakdown voltage. Particularly, when the second gate electrode 28 is composed of a plurality of electrode layers (two layers 26 and 27 in FIG. 2), the relaxation of concentration of the electric field can be facilitated. Third, the gate electrode 24 is constructed so that the first gate electrode 25 and the second gate electrode 28 are integrally formed. Thus, the gate electrode 24 can easily be formed in the recess region 29, and the miniaturized layer structure can be defined with ease.

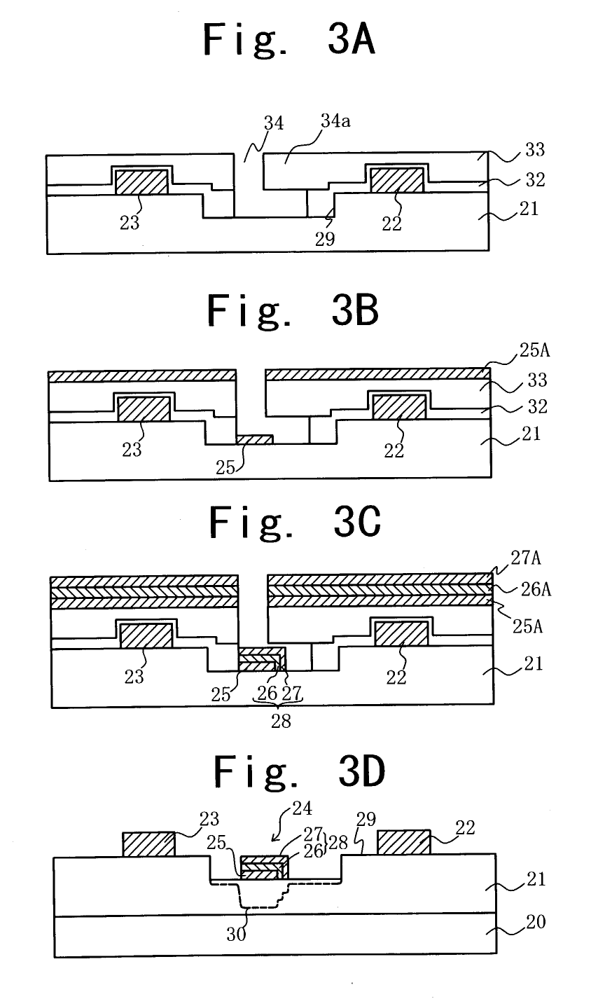

A description will now be given, with reference to FIGS. 3A through 3D, of a method of fabricating the semiconductor integrated circuit device shown in FIG. 2.

As shown in FIG. 3A, the GaAs epitaxial layer 21 is grown on the GaAs substrate 20 shown in FIG. 2 (the GaAs substrate 20 is omitted in FIGS. 3A through 3C for the sake of simplicity). Next, the drain electrode 22 and the source electrode 23 each composed of AuGe/Ni/Au is formed by the liftoff process. Then, the wafer is annealed so that the ohmic contact between the drain electrode 22 and the GaAs epitaxial layer 21 and the ohmic contact between the source electrode 23 and the GaAs layer 21 are formed. Thereafter, a window for forming the recess region 29 having a length of, for example, 0.8 μm is formed, and the GaAs epitaxial layer 21 is etched by a mixture etchant of hydrogen peroxide and hydrofluoric acid so that the recess region 29 can be formed. Then, two resist layers are applied, one of which is a lower resist layer 32 sensitive to only the electron beams, the other being an upper resist layer 33 sensitive to only the ultra-violet rays. An area on the upper resist layer 33 that corresponds to the gate electrode 24 and a size of 0.4 μm is selectively exposed and developed, so that an opening (window) 34 can be formed. Subsequently, the lower resist layer 32 is exposed and developed through the window 34 by the electron beam, so that an overhang portion 34a of the upper resist layer 33 extending from the drain side along the channel length can be formed. An opening formed in the lower resist 32 at that time is wider than the window 34 formed in the upper resist layer 33.

Next, as shown in FIG. 3B, a first gate metal 25A of, for example, palladium is deposited to a thickness of 100 μm (1000 Å). This step defines the first gate electrode 25 on the GaAs epitaxial layer 21. Palladium has a work function of 4.8 eV. Then, as shown in FIG. 3C, aluminum having a work function of 4.2 eV is deposited to a thickness of 100 μm (1000 Å), so that a second gate metal 26A is formed. The deposition is continuously carried out until aluminum is deposited on the GaAs epitaxial layer 21 along the sidewall of the first gate electrode 25. The above continuous deposition of aluminum forms the electrode layer 26 on the top of the first gate electrode 25 and the sidewall thereof facing the drain electrode 22. In other words, the top and sidewall of the first gate electrode 25 are covered by the electrode layer 26 of aluminum. The process of providing the second gate metal 26A employs an incident angle different from that used in the process of providing the first gate metal 25A. More particularly, the second gate metal 26A is deposited in an oblique direction so that a source for deposition relatively shifts. Alternatively, the wafer is moved around a fixed axis while the first gate metal 25A is deposited, and is additionally rotated on its axis while the second gate metal 26A is deposited. The similar effect can be brought by setting the rate of deposition at the time of forming the second gate metal 26A lower than that at the time of forming the first gate metal 25A. It is also possible to deposit the second gate metal 26A at a lower degree of vacuum than that for the first gate metal 25A.

Similarly, titanium having a work function of 3.9 eV is deposited to a thickness of 100 μm (1000 Å), so that a third gate metal 27A is formed. Finally, the lower resist layer 32, the upper resist layer 33, and the gate metals 25A, 26A and 27A are simultaneously removed by liftoff, so that the transistor shown in FIG. 3D, which is the same as that shown in FIG. 2, can be fabricated.

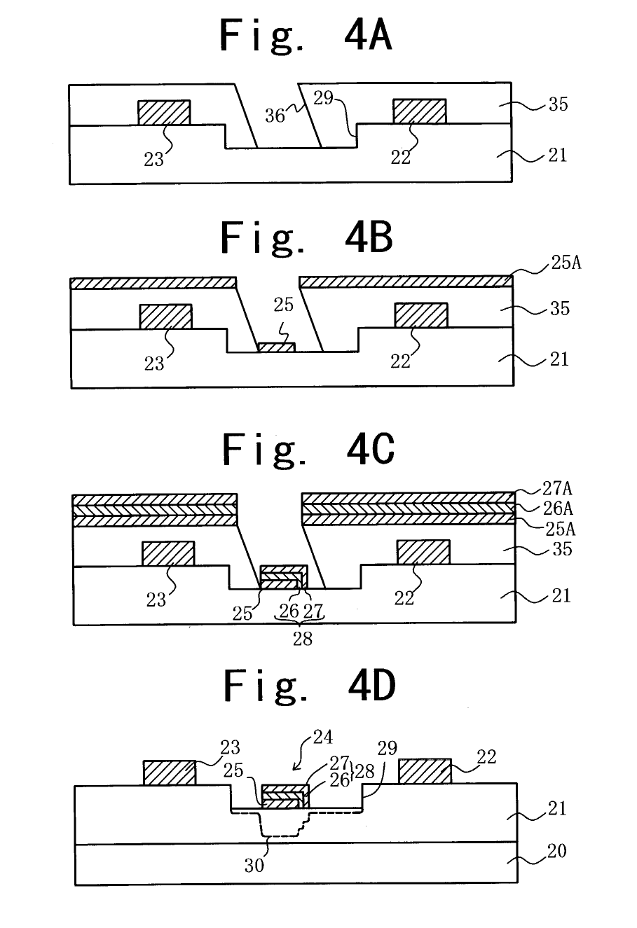

The above-mentioned first embodiment of the present invention employs multiple exposures in which the wafer is exposed multiple times with different opening sizes, so that the overhang shape can be defined. Alternatively, the transistor shown in FIG. 2 may be fabricated by dry etching in an oblique direction. This process is shown in FIGS. 4A through 4D.

Referring to FIG. 4A, the GaAs epitaxial layer 21 is etched to define the recess region 29, and a resist 35 sensitive to the electron beams or ultra-violet rays is applied to the wafer. Next, a mask (not shown for the sake of simplicity) is formed on the resist 35, and is dry-etched in an oblique direction (anisotropic etching in the oblique direction). The dry etching results in a slant opening (window) 36. By using the resist as a mask, as shown in FIG. 4B, palladium is deposited to a thickness of 100 μm (1000 Å) to form the first gate metal 25A. Then, as shown in FIG. 4C, aluminum is deposited to a thickness of 100 μm (1000 Å) to form the second gate metal 26A. At that time, the source of deposition may be moved so that the second gate metal 26A can be deposited in the oblique direction. Similarly, titanium is deposited to a thickness of 100 μm (1000 Å) to form the third gate metal 27A. Finally, liftoff is performed so that the resist 35 and the gate metals 25A, 26A and 27A are simultaneously removed. The transistor thus fabricated is illustrated in FIG. 4D, which is the same as FIG. 2.

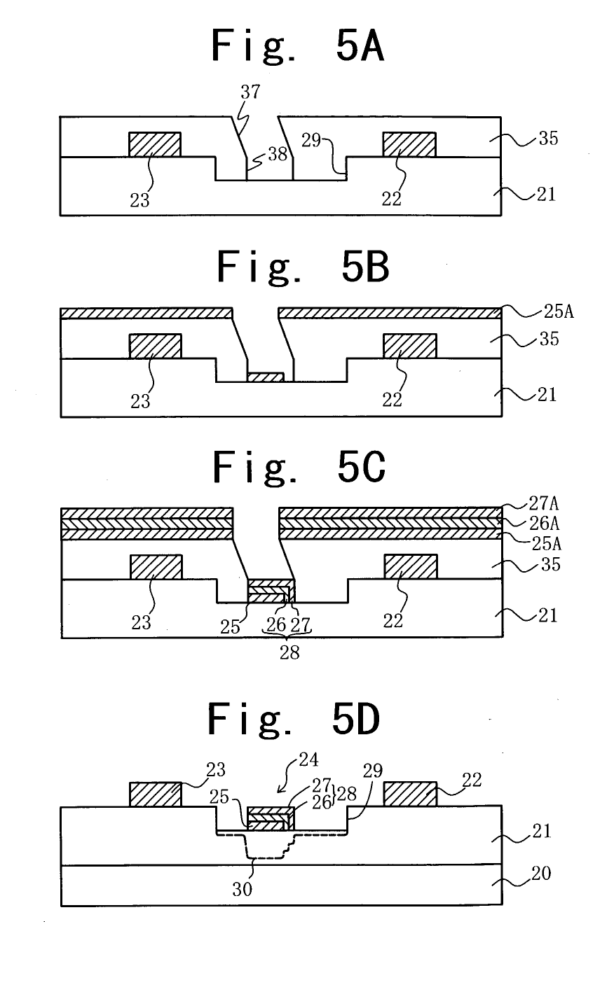

FIGS. 5A through 5D show yet another method of fabricating the transistor shown in FIG. 2 in which the resist mask 35 shown in FIGS. 4A through 4C is etched by the combination of oblique etching and vertical etching. Referring to FIG. 5A, the GaAs epitaxial layer 21 is etched to form the recess region 29, the resist 35 sensitive to the electron beams or ultra-violet rays is applied to the wafer. Next, a mask (not shown for the sake of simplicity) is formed on the resist 35, and is dry-etched in an oblique direction. The dry etching results in a slant opening (window) 37. Subsequently, the incident angle is changed so as to be perpendicular to the wafer surface, and the resist 35 is etched, so that a substantially vertical opening (window) 38 is formed in the resist 35. Then, palladium is deposited to a thickness of 100 μm (1000 Å) using the resist 35 as a mask so that the first gate metal 25A is formed, as shown in FIG. 5B. Then, the second gate metal 26A of aluminum is deposited to a thickness of 100 μm (1000 Å), and the third gate metal 27A of titanium is deposited to a thickness of 100 μm (1000 Å). Then, the resist 35 and the gate metals 25A, 26A and 27A are simultaneously removed by liftoff, so that the transistor shown in FIG. 5D can be fabricated. The above process may be varied so that the vertical window is formed in the resist 35 first and the oblique window is formed second.

As described above, the fabrication method according to the first embodiment of the present invention is capable of easily forming the gate electrode 24 composed of multiple layers by using the single window 34. It is to be noted that the materials and sizes mentioned before are just examples, and the present invention is not limited thereto.

(Second Embodiment)

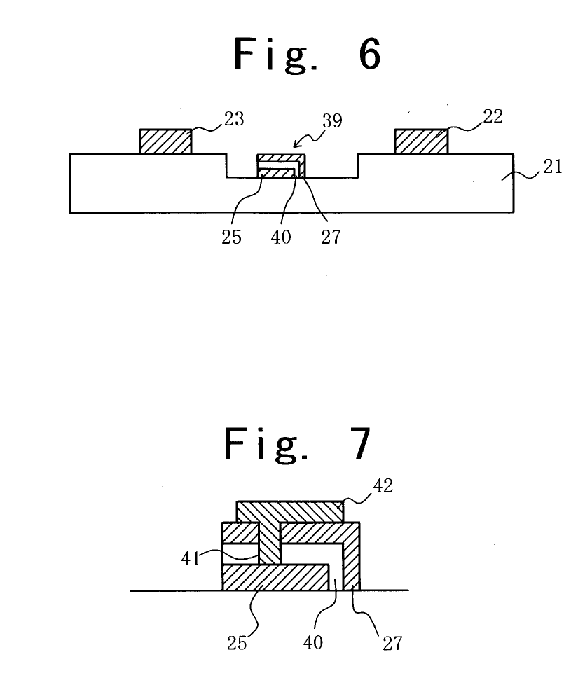

FIG. 6 is a cross-sectional view of a semiconductor integrated circuit device according to a second embodiment of the present invention. In FIG. 6, parts that are the same as those shown in the previously described figures are given the same reference numerals.

A gate electrode 39 used in the second embodiment is made up of the first gate electrode 25, the electrode layer 27 (hereinafter referred to as second gate electrode 27), and an interlayer insulating film 40. That is, the gate electrode 39 has a structure obtained by substituting the interlayer insulating film 40 for the electrode layer 26 of the gate electrode 24 employed in the first embodiment of the present invention. The gate electrode 39 has a three-layer structure physically. From electrical viewpoints, the gate electrode 39 has a two-layer structure composed of the first gate electrode 25 and the second gate electrode 27. The interlayer insulating film 40 is as thin as 100 μm (1000 Å), and only a very small surface depletion layer may be formed. In contrast to the prior art, there is only a very small influence of the surface depletion layer. The interlayer insulating film 40 may be a deposited film of Ti₃O₅. The second gate electrode 27 has a work function smaller than the first gate electrode 25. As shown in FIG. 7, a via hole 41 is formed in the second gate electrode 27 and the interlayer insulating film 40, and is full of a gate wiring line 42. The gate wiring line 42 electrically connects the first gate electrode 25 and the second gate electrode 27.

The use of the interlayer insulating film 40 makes it possible to form the gate electrode 39 made of the electrodes 25 and 27 slightly separated from each other via the insulating film 40 so that the electrodes 25 and 27 having different work functions can be self-aligned.

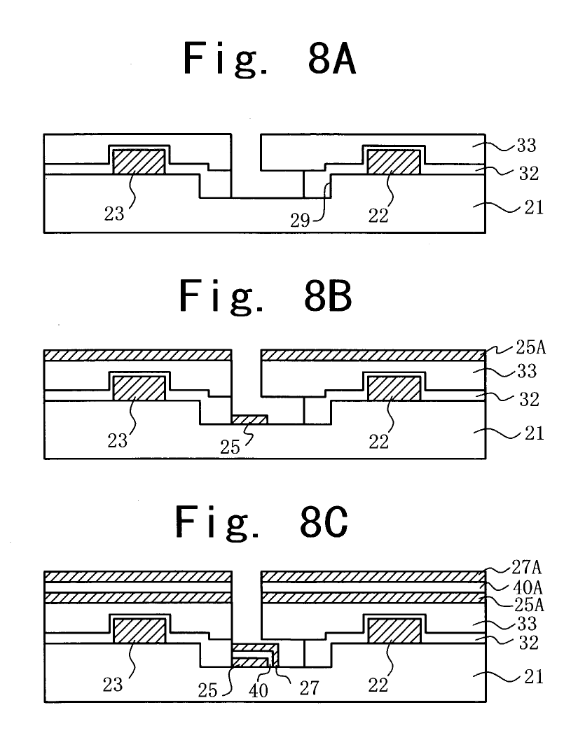

FIGS. 8A through 8C are cross-sectional views illustrating a method of fabricating the semiconductor integrated circuit device shown in FIG. 6. The step shown in FIG. 8A is the same as that shown in FIG. 3A mentioned before. The step shown in FIG. 8B is the same as that shown in FIG. 3B. Referring to FIG. 8C, an interlayer insulating film 40A of Ti₃O₅ is deposited to a thickness of 100 μm (1000 Å). Next, the second gate metal 27A of aluminum or titanium is deposited to a thickness of 100 μm (1000 Å). Then, the resist layers 32 and 33, the first gate metal 25A, the insulating film 40A and the second gate metal 27A are simultaneously removed by liftoff. Then, the via hole 41 is formed in the second gate electrode 27 and the interlayer insulating film 40 by dry etching. Finally, the gate wiring lien 42 is provided.

The second embodiment of the present invention has the following advantages. First, the gate electrode 39 has the single structure, to which the single gate wiring line can be applied. Second, the gate electrode 39 is composed of the first electrode 25 and the second electrode 27 that are integrally formed and arranged side by side along the channel length via via the insulating film 40. Thus, the depletion layer gently changes at the drain side and the concentration of the electric field is relaxed. This leads to enhancement of the breakdown voltage between the gate and drain of the transistor. Third, the gate electrode 39 can easily be formed in the recess region 29 because it is made of the first gate electrode 25 and the second gate electrode 27 integrally formed. In addition, the transistor can be miniaturized with ease. Fourth, the first gate electrode 25 and the second gate electrode 27 can be self-aligned.

The gate electrode 39 is not limited to two electrodes but may be composed of three electrodes or more. For instance, the three-layer structure has an interlayer insulating film between the second and third gate electrodes. The materials and sizes mentioned before are just examples, and the present invention is not limited thereto. The present invention includes not only the above-mentioned MEFETs but also other types of compound semiconductor devices.

The present invention is based on Japanese Patent Application No. 2002-070967 filed on Mar. 14, 2002, the entire disclosure of which is hereby incorporated by reference.

The present invention is not limited to the specifically disclosed embodiments, and other embodiments, variations and modifications may be made without departing from the scope of the present invention.

What is claimed is:

1. A semiconductor integrated circuit device comprising:
a semiconductor layer on a substrate;
a first gate electrode formed on the semiconductor layer; and
a second gate electrode that is formed on the semiconductor layer and is adjacent to a sidewall of the first gate electrode along a channel length,
the first and second gate electrodes having different work functions.

2. The semiconductor integrated circuit device according to claim 1, wherein the second gate electrode contacts the first gate electrode.

3. The semiconductor integrated circuit device according to claim 1, further comprising an insulating layer interposed between the first gate electrode and the second gate electrode.

4. The semiconductor integrated circuit device according to claim 1, wherein the first gate electrode is wider than the second gate electrode along the channel length.

5. The semiconductor integrated circuit device according to claim 1, the second gate electrode is located at a side of a drain electrode formed on the semiconductor layer.

6. The semiconductor integrated circuit device according to claim 1, wherein the first gate electrode has a work function greater than the second gate electrode.

7. The semiconductor integrated circuit device according to claim 1, wherein the second gate electrode has a cross section having an inverted L shape.

8. The semiconductor integrated circuit device according to claim 1, wherein the second gate electrode comprises a plurality of electrode layers.

9. The semiconductor integrated circuit device according to claim 1, wherein the second gate electrode comprises a plurality of electrode layers, which have respective work functions that become smaller in order from the first gate electrode towards a drain electrode.

10. The semiconductor integrated circuit device according to claim 1, wherein the first gate electrode is made of a material selected from a group of palladium, aluminum, titanium, tungsten, tungsten silicide, titanium tungsten, nickel, platinum, gold, silver, copper, indium, magnesium, tantalum, molybdenum, antimony, chromium, tin, tungsten nitride, and titanium tungsten nitride, and the second gate electrode is made of another material selected from the group.

11. The semiconductor integrated circuit device according to claim 1, wherein the semiconductor layer is a compound semiconductor layer.

12. A method of fabricating a semiconductor integrated circuit device comprising the steps of:
(a) forming a mask on a semiconductor layer provided on a substrate so that the mask has an overhang portion that extends along a channel length;
(b) depositing a first gate electrode material via the mask;
(c) depositing a second gate electrode material on the semiconductor layer so as to be adjacent to a sidewall of the first gate electrode material, the second gate electrode material having a work function different from that of the first gate electrode material.

13. The method according to claim 12, wherein the step (a) comprises the steps of laminating a plurality of resists for forming the mask, and exposing the plurality of resists so that windows having different sizes can be formed.

14. The method according to claim 12, wherein the step (a) comprises the steps of forming a resist for forming the mask, and forming the mask by etching that is anisotropic in an oblique direction.

15. The method according to claim 14, further comprising a step of etching the resist substantially vertically before or after the mask is etched obliquely.

16. The method according to claim 12, wherein the step (c) continues to deposit the second gate electrode material until the second gate electrode material covers the sidewall of the first gate electrode material deposited by the step (b).

17. The method according to claim 12, wherein the step (c) forms a second gate electrode made of the second gate electrode material so as to contact a first gate electrode made of the first gate electrode material.

18. The method according to claim 12, wherein the step (c) forms a second gate electrode made of the second gate electrode material so that an interlayer insulating film is interposed between a first gate electrode made of the first gate electrode material and the second gate electrode.

19. The method according to claim 18, further comprising a step of depositing the interlayer insulating film via the mask before the step (c).
